(19) United States
(12) Patent Application Publication
(10) Pub. No.: US 2014/0342291 A1
(43) Pub. Date: Nov. 20, 2014

(54) Novel Dual-Tone Resist Formulations And Methods

(71) Applicant: Board of Regents, The University of Texas System, Austin, TX (US)

(72) Inventors: C. Grant Willson, Austin, TX (US); Wei-Lun Kane Jen, Sugarland, TX (US); Brandon Mark Rawlings, Austin, TX (US); Jeffrey Ryan Strahan, Austin, TX (US)

(73) Assignee: Board of Regents, The University of Texas System, Austin, TX (US)

(21) Appl. No.: 14/242,223

(22) Filed: Apr. 1, 2014

Related U.S. Application Data
(63) Continuation of application No. 13/090,502, filed on Apr. 20, 2011.
(60) Provisional application No. 61/326,860, filed on Apr. 22, 2010.

(51) Int. Cl. G03F 7/213; G03F 7/004

(52) U.S. Cl. CPC G03F 7/213; G03F 7/004
USPC 430/323; 430/322

(57) ABSTRACT

Dual tone photoresist formulations comprising a photoacid generator are described and employed in fabrication techniques, including methods of making structures on substrates, and more particularly, methods of making electronic devices (e.g. transistors and the like) on flexible substrates wherein two patterns are formed simultaneously in one layer of photoresist.

### FIELD OF THE INVENTION

This invention relates in general to dual-tone photoresists and methods of using dual-tone resists. In one aspect, this invention is directed to photoresist formulations which produce a positive or negative image depending upon processing conditions. In another aspect, this invention relates in one embodiment to liquid, dual-tone photoresist formulations comprising a photoacid generator.

### BACKGROUND OF THE INVENTION

Conventional semiconductor masking processes involve microfabrication, that is, the definition of very small patterns of protective material, such as silicon dioxide, on a semiconductor surface. Normally, a layer of photosensitive resist (“photoresist”) material is deposited on the surface of a protective SiO₂ layer on a substrate. Typical photoresist materials comprise organic materials which undergo chemical changes, such as molecular cross-linking, when subjected to radiation. The photoresist layer is illuminated with radiation (e.g. ultraviolet light) passed through a photo mask containing the desired pattern to be formed in the photo-resist layer (FIG. 1, step B). The exposed resist film is then developed typically by immersion in a developer solvent (FIG. 1, step C) to generate three-dimensional relief images. The exposure may render the resist film more soluble in the developer, thereby producing a positive-tone image of the mask. Conversely, it may become less soluble upon exposure, resulting in generation of a negative-tone image. The resist film that remains after the development functions as a protective mask. The resist image is then transferred into the substrate by etching (FIG. 1, step D) and related processes. The resist film must “resist” the etchant and protect the underlying substrate while the bared areas are being etched. In this manner, the etching transfers the photoresist patterns into the substrate. The remaining resist film is finally stripped, leaving an image of the desired circuit in the substrate. The process is repeated many times to fabricate complex semiconductor devices.

Thus, photoresists are photosensitive, etch resistant materials which change their solubility after exposure to light. In one embodiment, they are novolac (sometimes “novolak”) resins (FIG. 2, part A) and a diazonaphthoquinone (abbreviated “DNQ”) attached to the polymer backbone or added to the resist formulation (see FIG. 2, part B). The diazonaphthoquinone acts as an inhibitor which decreases the solubility rate of diazonaphthoquinone-novolac films in basic solutions, i.e. dissolution inhibitor), until exposed to light (FIG. 2, part B) at which point it acts as a dissolution promoter.

A dual-tone photoresist is defined as a photoresist capable of producing positive and negative latent images in a single layer. U.S. Pat. No. 4,767,723 to Hinsberg et al. (hereby incorporated by reference) describes a dual-tone photoresist comprised of novolac resin, a diazoquinone, and a photoactive additive which is a bis-aryl azide. While useful, this photoresist is not capable of surviving a plasma or reactive ion etch process and retaining the latent image due to the exposure of the azide during the plasma processing.

Thus, novel and improved photoresist formulations are needed.

### SUMMARY OF THE INVENTION

The present invention contemplates creating structures, and in particular, electronic devices, on substrates. While a variety of substrates can be used (including solid, inflexible substrates), in a preferred embodiment, the present invention contemplates using a flexible (or conformal) substrate. Structures economically formed on a flexible substrate can be viewed as a potentially important technology for circuitry in various electronic devices or components such as display backplanes, portable computers, flexible displays, pagers, memory elements in transaction cards, identification tags (e.g. radiofrequency ID tags), and even large aperture radar, where ease of fabrication and mechanical flexibility are advantageous. Producing thin film semiconductor devices on flexible substrates is desired, particularly because these supports would be lighter weight, they can be made into different shapes (because it is not rigid), and potentially lead to cheaper manufacturing by allowing roll-to-roll processing.

During fabrication of a semiconductor device, a highly accurate alignment of features (e.g. the gate electrode with the source and drain electrode) is typically needed, which can be a challenge. Usually, the source and drain electrodes on a substrate are aligned to the gate using alignment marks. Such patterning is difficult, and manufacturing processes are particularly complicated. Further, sequential layer alignment has limited accuracy on flexible substrates.

The present invention relates in general to processes and compositions, including dual-tone photoresists that enable alignment of structures (e.g. the gate with the source and drain electrode) on flexible substrates. In one aspect, this invention is directed to photoresist formulations which produce a positive or negative image depending upon processing conditions, allowing for the simultaneous patterning of isolation and gate structures on a substrate (particularly a flexible substrate). This permits the alignment of structures in one step (e.g. the alignment of the gate and source and drain). In another aspect, this invention relates to liquid, dual tone positive photoresist formulations comprising a photoacid generator. In another aspect, this invention relates to liquid, dual tone photoresist formulations comprising a novolac resin, a diazonaphthoquinone, photogenerator of strong acid, and a crosslinker Accordingly, this invention contemplates a novel photoresist formulation which is capable of surviving a dry etch process while retaining the latent image. In one embodiment, the photoresist formulation builds on the DNQ novolac-type positive tone i-line resist by the addition of a strong photoacid generator (PAG) such as TPS nonaflate and a crosslinker such as 1,4-benzenedimethanol (FIG. 3). There are many other PAGs and crosslinkers (FIG. 4) known in the art which can be employed. For example, any compound that is a latent precursor to a polyfunctional carbocation can be a crosslinker. This photoresist requires only light to produce a positive image but both UV light and heat to produce a negative tone responses.

To mitigate the lost of the negative-tone latent image during the RIE plasma etch process, we designed a variation on the above-mentioned novolac/DNQ based dual-tone photoresist system, which incorporates a thermally activated, chemically amplified crosslinker and a photoacid generator. In this design, the photoacid generator provides the spectral selectivity for the negative-tone response, while the thermally activated crosslinker imposes an additional bake requirement for the activation of the cross-link reaction and the realization of the negative-tone latent images.

It is not intended that the present invention be limited by the nature of the photoacid generator (PAG). There are several issues to be considered in the choice of the PAG, including but not limited to sufficient radiation sensitivity to ensure adequate strong acid generation for good resist sensitivity, absence of metallic elements, temperature stability, dissolution inhibition, and its absorbance spectrum, etc. In one embodiment, triarylsulfonium (e.g. triphenylsulfonium nonaflate, or tri-p-hydroxyphenylsulfonium triflate) or diaryliodonium salts are preferred because of their generally easy synthesis, thermal stability, high quantum yield for strong acid (and also radical) generation, and the strength and nonvolatility of the acids they supply. Simple onium salts are directly sensitive to DUV, X-ray and electron radiations, and can be structurally tailored, or mixed with photosensitizers, to also perform well at mid-UV and longer wavelengths. However, onium salts are ionic and some phase separate from some apolar polymers, or do not dissolve completely in some casting solvents. Nonionic PAGs such as phloroglucinyl and o,o-dinitrobenzyl sulfonates, benzylsulfones and some 1,1,1-trihalides are more compatible with hydrophobic media in general, although their thermal stabilities and quantum yields for acid generation are often lower. It is also not intended that the present invention be limited by the developing solvents used. In one embodiment, the developing solvent can be an aqueous solution of an alkali metal hydroxide, such as sodium hydroxide or tetramethylammonium hydroxide.

It is also not intended that the present invention be limited by the nature of the etchant. In one embodiment, a useful etchant for the passivation layer is phosphoric acid. Other etchants include aqueous buffered hydrofluoric acid or plasma etch (RIE) based on fluorine chemistry and the like. The present invention was developed using a plasma etch based on CF₄ plus helium gas.

It is also not intended that the present invention be limited to only certain wavelengths. Different additives respond to different wavelengths. In one embodiment, for example, the additive that brings about acceleration of resist dissolution upon activation can be diazonaphthoquinone sulfonate esters that absorb at wavelengths up to 400-500 nanometers. In one embodiment, for example, the additive that brings about acceleration of resist dissolution upon activation can be diazonaphthoquinone sulfonate esters that absorb at wavelengths less than 300 nanometers. Such a dual-tone photoresist system exhibits spectral selectivity, as its exposure response is determined by the wavelength of the incident UV light. This spectral selectivity enables the dual-tone photoresist to store two distinct latent images based on the wavelength of the incident exposure light, allowing the patterning of two device structures in one lithographic exposure step. Furthermore, the negative image can be activated only by a combination of heat and light of proper spectral range.

It is also not intended that the present invention be limited by the nature of the flexible substrate used. In one embodiment, the flexible substrate is a thin, metal substrate (e.g. a metal foil or steel foil). In one embodiment, the flexible substrate is a thin, polymer film substrate (e.g. comprising polyimide, polyester, etc.).

The new type of dual tone resist (described above) and its use in fabrication methods (described in more detail below), enable the accurate alignment of two levels of an electronic device structure on a flexible substrate. The method requires the new photoresist together with one of several known techniques for achieving simultaneous exposure (and in one embodiment, with wavelength separation).

In one embodiment, the present invention contemplates a method of making two patterns in one layer of photoresist, comprising the steps of: (a) providing a substrate, a dual-tone photoresist (as described herein), a source of radiation, and a mask, said mask having transparent areas, opaque areas and areas transparent to selective wavelengths of radiation; (b) forming one or more (typically a plurality of) thin layers over said substrate; (c) coating the top layer (e.g. of said plurality of layers) with said dual-tone photoresist (optionally, adhesion of the photoresist can be enhanced through use of adhesion promoters that are well known in the art, such as hexamethyldisilazane); (d) exposing said photoresist to radiation, said radiation coming from said source of radiation and passing through said mask, said mask positioned on top of said photoresist under conditions such that two patterns are generated in said layer of photoresist, said patterns defined by i) radiation-exposed regions of the photoresist, ii) unexposed regions of the photoresist, and iii) at least one radiation-exposed region of the photoresist capable of a negative tone response; and e) treating said at least one radiation-exposed region of the photoresist capable of a negative tone response under conditions wherein a negative tone response is achieved. In one embodiment, one or more of said layers comprise silicon.

In one embodiment, the present invention contemplates a method of making two patterns in one layer of photoresist, comprising the steps of: (a) providing a substrate, a dual-tone photoresist (as described herein), a source of radiation, at least one optical filter and first and second masks; (b) forming one or more (typically a plurality of) thin layers over said substrate; (c) coating the top layer (e.g. of said plurality of layers) with said dual-tone photoresist (optionally, attachment of the photoresist can be enhanced with an adhesive compound); (d) exposing said photoresist to radiation of wavelengths of a first type so as to activate the positive tone, said radiation coming from said source of radiation and passing through said optical filter, said optical filter positioned above said first mask, said first mask positioned on top of said photoresist; and (e) exposing said photoresist to radiation of wavelengths of a second type so as to activate the negative tone, said radiation coming from said source of radiation and passing through said second mask, said mask positioned on top of said photoresist. In one embodiment, said first and second masks are chromium-on-quartz masks. In one embodiment, said optical filter is a long-pass filter.

In another embodiment, the present invention contemplates a method of making two patterns in one layer of photoresist, comprising the steps of: (a) providing a substrate, a dual-tone photoresist (as described herein), a source of radiation, and a two-tone mask, said mask having transparent areas, opaque areas and areas transparent to selective wavelengths of radiation; (b) forming a plurality of thin layers over said substrate, at least one of said layers comprising silicon; (c) coating the top layer of said plurality of layers with said dual-tone photoresist; (d) exposing said photoresist to radiation, said radiation coming from said source of radiation and passing through said mask, said mask positioned on top of said photoresist under conditions such that two patterns are generated in said layer of photoresist, said patterns defined by i) radiation-exposed regions of the photoresist having a positive tone response, ii) unexposed regions of the photoresist, and iii) at least one radiation-exposed region of the photoresist capable of a negative tone response; and e) treating said at least one radiation-exposed region of the photoresist capable of a negative tone response under conditions wherein a negative tone response is achieved. In one embodiment of the above-described methods, said treating of step (e) comprises exposure to heat (e.g. a bake step).

In one embodiment of the above-described methods, the process further comprises developing the photoresist by treatment with a solvent, under conditions whereby the radiation-exposed regions of the photoresist having a positive tone response are removed. In one embodiment of the above-described methods, the process further comprises subjecting said plurality of layers to etching (e.g. reactive ion etching), wherein the unexposed regions of the photoresist do not become negative tone because there is no heating step (i.e. the region is maintained below critical temperature).

In one embodiment of the above-described methods, the mask is a two-tone mask (as defined below) where the layer alignment is controlled and defined in the manufacture of the mask. In another embodiment, there are two masks where alignment marks are used for alignment but because of the dual tone, the substrate is held in place between exposures (i.e. need not be moved).

In one embodiment of the above-described methods, one of said plurality of layers is selected from the group consisting of a gate dielectric material, an active material and a passivating dielectric.

In one embodiment of the above-described methods, said substrate is a flexible substrate. In a preferred embodiment, said flexible substrate is part of a device, said device selected from the group consisting of display backplanes, portable computers, flexible displays, pagers, memory elements in transaction cards, identification tags (e.g. radiofrequency ID tags), and large aperture radar.

### DEFINITIONS

In a “positive” working photoresist system, the photoresist system is altered upon exposure in such a manner that it is subsequently soluble in the developer (e.g., aqueous base). The exposed areas of the photoresist film are removed upon developing, and the free unprotected areas on the substrate surface correspond to the transparent parts on the photomask.

In the past, the term “negative” refers to a photoresist which after exposure in a suitable solvent is insoluble, whereas the unexposed resist zones are dissolved by the developer. As a result, free and unprotected zones are obtained on the substrate surface which correspond to the opaque parts of the photomask.

In one embodiment, the present invention contemplates a dual-tone resist that displays a wavelength dependent resist tone response, e.g. the resist is a) insoluble in developer when not exposed at all to heat or light, b) soluble in developer (e.g. base) when exposed to long wavelengths of light (i.e. a positive tone response). However, when exposed to heat and wavelengths short enough to create acid, the resist is insoluble in developer (i.e. a negative tone response).

In one embodiment, the “dual-tone photoresist” of the present invention contemplates a diazoquinone together with a photoacid generator (PAG) and a crosslinker. Based on the evaluation of the candidate cross-linkers and PAGs, one embodiment of the functional formulation of the dual-tone, thermally activated photoresist comprises of a commercial novolac polymer with DNQ PAC (photoactive compound-dissolution inhibitor) in solvent, 1-5 wt % of PAG, and 3-8 wt % of cross-linker. In one embodiment, the preferred formulation of the dual-tone, thermally activated photoresist consists of a commercial novolac polymer with DNQ PAC in PGMEA (propylene glycol methyletheracetate) solvent, 3 wt % of TPS (triphenylsulphonium) nonaflate PAG, and 5 wt % of 1,4-benzenedimethanol cross-linker. This preferred photoresist was used for the subsequent dual-tone lithography and etch process development and functional device print tests. This photoresist was used for the subsequent dual-tone lithography and etch process development and functional device print tests.

A “two tone mask” (or “dichromatic” mask) is a mask having transparent areas, opaque areas and areas transparent to specific wavelengths of radiation. For example, a first transparent area may permit a first range of wavelengths to pass, while a second transparent area may permit a second range of wavelengths to pass. It is not intended that the present invention be limited by the nature of the two tone mask. In one embodiment, the present invention contemplates a chromium-on-quartz photomask having certain transparent areas which transmit mid-UV light and other transparent areas which transmit only near-UV light. The mask can be fabricated on a quartz substrate that transmits all wavelengths above 200 nanometers. The opaque mask elements can be chromium that is opaque to all activating wavelengths. The optical filter elements can be films of a common positive diazonaphthoquinone-novolac photoresist such as those commonly used in microcircuit fabrication, which transmit above 350 nanometers and are opaque below 350 nanometers at thicknesses greater than 3 microns (or titanium dioxide TiO2). Examples of two tone masks useful for this invention are described by Hinsberg, U.S. Pat. No. 4,767,723, hereby incorporated by reference.

In another embodiment, one can use two chromium-on-quartz masks together with optical filters (e.g. two exposures with two different masks). In this case a long-pass filter is applied above the photomask for positive tone exposure that limits the light to wavelengths greater than that required to activate the photoacid generator (PAG). Then the negative region is exposed through the mask to broad-band wavelengths without a filter. The positive tone DNQ absorbs from 200-440 nm PAG absorbs from below 200 nm to up to 290 nm. Thus, a UV exposure with a 345 nm long-pass filter only activates the positive tone DNQ, while a broad band UV exposure without a filter activates both the positive tone DNQ and the negative tone PAG. In the present invention, the addition of a thermal activation requirement (e.g. bake step) enables differentiation between the intentional photomask exposure and the unavoidable RIE plasma exposure. One must control the temperature during the plasma etch to prevent acid-catalyzed reactions from occurring.

Thus, it is possible to carry out dual-tone exposure using either binary photomasks or dichromatic photomasks. Instead of single exposure with one dichromatic photomask to produce both the positive-tone and the negative-tone latent images (FIG. 7a), the dual-tone photoresist can be exposed sequentially using two binary photomasks and different wavelengths of UV light to produce the similar positive-tone and negative-tone latent images (FIG. 7b).

The sequential aligned exposures with two binary photomasks are usually done without unloading the substrate between the exposures in a typical manufacturing process. This minimizes the effect of substrate distortion and incurs only mask-to-mask alignment errors between the two patterns.

“Reactive ion etching” or “RIE” is a process that uses a chemically reactive plasma to remove material on the substrate (e.g. silicon wafer). In one embodiment, the resist formulation of the present invention is able to survive RIE (i.e. at the end of the process, there must be enough resist remaining such that the desired area is not damaged). From testing it has been observed that the etch rate of the silicon oxide film increased exponentially with increasing etch power and decreased linearly with increasing etch pressure. However, at high etch power there is considerable photoresist film loss. Data suggests (see below) that a CF₄/He gas mixture has the highest selective between silicon oxide etch and photoresist film loss at a given etch power and pressure, compared to that of the CF₄/O₂mixture and the pure CF₄ etch gas. In one embodiment, the present invention contemplates using a CF₄/He gas mixture. On the other hand, better etch depths are achieved with the CF₄/O₂ mixture. In one embodiment, the present invention contemplates a preferred etch recipe of 15 scorn CF₄, 5 sccm O₂, 50 mTorr, and 150 W; this recipe has the least photoresist film loss during etch, while producing a good etch rate for a particular etch tool.

Certain complications were observed (discussed below) during etching. In order to resolve them, the flood exposure of the previously unexposed dualtone photoresist was moved to precede the positive-tone etch step instead of following the said etch step, ensuring that a “crust” fanned during etch did not interfere with the flood exposure of the photoresist. A short O₂ plasma ash was also added right after the positive-tone etch step to remove the crust prior to the negative-tone image development.

“I-line” lithography refers to the wavelength used for exposure. To achieve smaller dimensions, the wavelength was been reduced over the years from g-line (436 nm) to i-line (365 nm), KrF laser (248 nm) to ArF laser (193 mu), and continuing on to EUV (13.5 nm).

### DESCRIPTION OF THE FIGURES

FIG. 1 is a schematic showing the typical steps [e.g. exposure of the resist to radiation through a mask (step B), development of the resist with a developer solution (step C), etching of the substrate (step D), etc.] in conventional (prior art) fabrication of semiconductor devices on a substrate.

FIG. 2 shows the structures of typical (prior art) novolac resins (part A) which have a diazonaphthoquinone (abbreviated “DNQ”), the properties of which change upon exposure to radiation (part B).

FIG. 3 shows preferred reagents of one embodiment of a photoresist formulation of the present invention.

FIG. 4 shows alternative cross-linkers contemplated for alternative embodiments of the photoresist formulation of the present invention.

FIG. 5A-C is a schematic showing one embodiment of a method of printing 2 patterns (isolation and gate) onto 1 layer of resist using a thermally activated dual tone resist (top layer, 10) of the present invention (requiring both heat and light for a negative tone). Portions of the resist (top layer, FIG. 5A) are exposed to radiation through a two-tone mask (FIG. 5B, arrow) to create (depending on the wavelengths transmitted through the mask) a positive response (“+”) in the exposed areas. However, a heating step (FIG. 5C) is required for the negative response (“−”). The bottom layer (20) is the substrate, e.g. a flexible. substrate).

FIG. 6 is a schematic showing an overview of one embodiment of the dual-tone lithography method of the present invention for patterning of self-aligned structures.

FIG. 7 shows two dual-tone exposure schemes contemplated by the present invention: A. Single exposure with one dichromatic photomask. B. Two sequential exposures with two binary photomask and different wavelengths of UV light.

FIG. 8A-E shows dual-tone lithography that is not compatible with reactive ion etch. The UV radiation generated by the etchant plasma during the RIE process flood exposes the dual-tone photoresist, resulting in the loss of the negative-tone latent image. More specifically, the problems with prior art dual tone resist are shown, i.e. that the reactive ion etching (“RIE”) step (step shown in FIG. 8D) destroys the latent gate pattern because, with the existing dual tone resist, this exposure activates the crosslinker in the unexposed region (becoming negative tone) so that the desired pattern (step shown in FIG. 8E) cannot be achieved. Prior to the RIE step, the dual-tone resist (top layer, step shown in FIG. 8A) was subjected to photolithography using a mask (not shown) to create both a positive and negative latent image (step shown in FIG. 8B), followed by a development step to remove the positive resist (step shown in FIG. 8C).

FIG. 9 shows an embodiment of the dual-tone, thermally activated photoresist method that is compatible with reactive ion etch process. The dual tone resist is shown deposited on the substrate. Following the dual tone exposure (Step A), there is a heating or bake step (Step B). The post-exposure bake requirement (Step B) for the negative-tone response provides the differentiation between the intentional negative tone patterning and the flood exposures in the RIE process.

FIG. 10A-G shows successful generation of both isolation and gate level structure with one layer of dual-tone resist (10). FIG. 10A-G is a schematic showing the overall process for simultaneous fabrication of the isolation and gate structures using the dual tone resists (top layer) of the present invention on a flexible substrate (bottom layer, 20). The dual-tone photoresist (top layer, step shown in FIG. 10A) is exposed to radiation through a mask (not shown) to create two latent images in one step (step shown in FIG. 10B). The positive resist is removed in a developing step (step shown in FIG. 10C). During the etching step (step shown in FIG. 10D), the resist maintains the pattern and acts as a mask. The gate pattern is then developed (step shown in FIG. 10E), followed by another etching step (step shown in FIG. 10F), and finally the resist is removed (step shown in FIG. 10G).

FIG. 11 shows optical microscope images (column B) and the corresponding profilometer traces (column C) of a patterned photoresist sample on a silicon wafer at several process stages (column A). A top-down optical microscope image in column B shows a sample device area, with the dark blue line (row 2) denoting the profilometer scan area across the positive-tone photoresist. The profilometer trace (column C, row 2) shows a 900 nm tall photoresist structure after the positive-tone development.

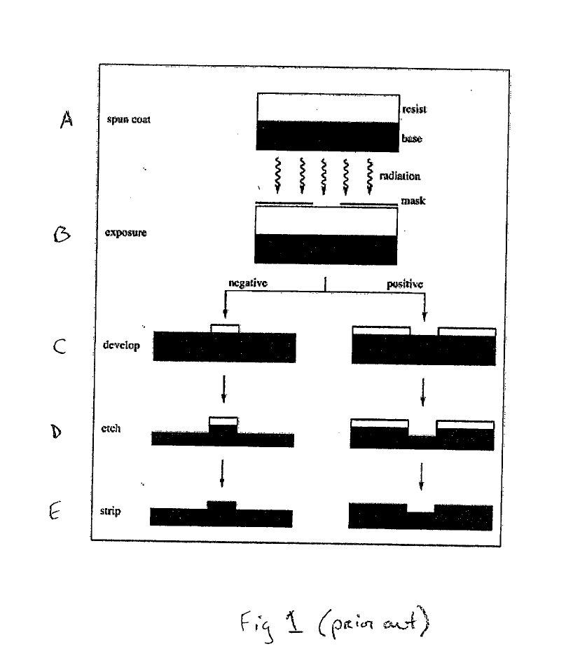

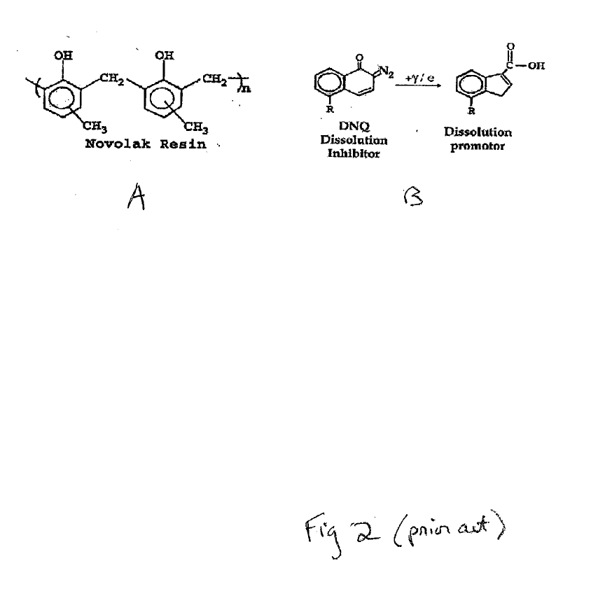

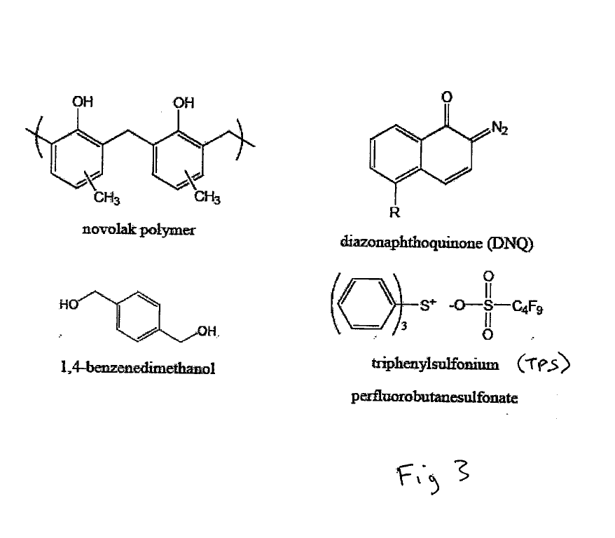

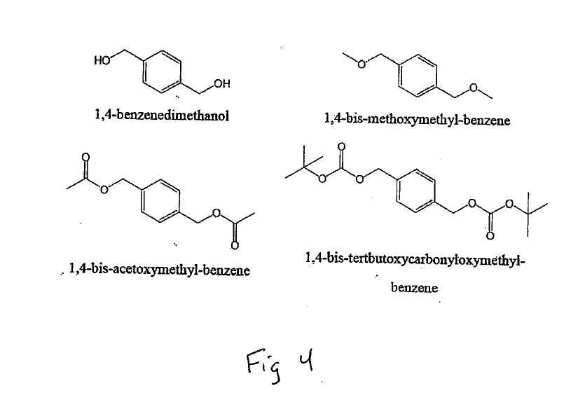

The sample was then etched by RIE to transfer the positive-tone image into the substrate (column A, row 3), and developed again to remove previously unexposed photoresist, leaving behind the negative-tone device image. Column B (row 3) shows a top-down image of the dual-tone photoresist sample with the positive-tone image etched into the substrate and negative-tone photoresist image left. The profilometer trace (column C, row 3) shows approximately 550 nm of photoresist remaining after the positive-tone structures are etched into the silicon substrate.

Finally, the sample was etched again by RIE to transfer the negative-tone image into the substrate (column A, row 4), then stripped of the photoresist, leaving behind the two aligned layers of device structures in the substrate. Column B (row 4) shows a top-down image of the dual-tone photoresist sample with both positive-tone and negative-tone images etched into the substrate. The profilometer trace (column C, row 4) shows ˜100 nm tall positive-tone structures and ˜200 nm tall negative-tone structures.

FIG. 12 shows the silicon oxide etch rate in the Trion etcher. The etch rate increased linearly with etch time. The following parameters were held constant: 15 sccm CF₄, 5 sccm O₂, 250 mTorr, and 100 W.

FIG. 13 shows the silicon oxide etch depth as a function of etch power in the Trion etcher. The following parameters were held constant: 15 sccm CF₄, 5 sccm O₂, 250 mTorr, and 5 min.

FIG. 14 shows the silicon oxide etch depth as a function of etch pressure in the Trion etcher. The following parameters were held constant: 15 sccm CF₄, 5 sccm O₂, and 5 min.

FIG. 15 show the Normalized photoresist film lost during silicon oxide etches in the Trion etcher. The following parameters were held constant: 15 sccm CF₄, 5 sccm O₂, and 5 min.

FIG. 16 shows the photoresist loss as a function of gas compositions in the Trion etcher. The CF₄/He gas mixture had significantly less photoresist loss than the CF₄/O₂ gas mixture. The following parameters were held constant: 15 sccm CF₄ and 5 min.

FIG. 17 shows the: Silicon oxide etch rates as a function of gas compositions in the Trion etcher. The choice of the secondary etch gas had no significant impact on the etch rate for a given etch power and pressure. The following parameters were held constant: 15 sccm CF₄ and 5 min.

FIG. 18 shows the optical microscope image of the patterned dual-tone photoresist samples: A. before development; B. during development; and C. after development.

### DESCRIPTION OF THE INVENTION

As noted above, during fabrication on a substrate using lithography, there is typically a requirement for a highly accurate alignment of the structures (e.g. the gate electrode with the source and drain electrode. Flexible substrates can complicate this alignment, since the flexible substrate can stretch and distort in between and during the isolation and gate lithography.

The novel photoresist material of the present invention avoids the errors introduced when two separate lithography steps are used to achieve layer-to-layer alignment during patterning on flexible substrates. The novel photoresist material of the present invention allows for printing 2 patterns (e.g. isolation and gate) onto 1 layer of resist, and (most importantly) the patterns survive later steps (e.g. etching). This invention enables the use of a single layer of dual tone resist in place of multiple resist layers. Thus, the present invention enables a lithographic process that allows simultaneous imaging of two levels of a structure into the photoresist. That is to say, the process enables the transfer of two levels of structure into the substrate, from one layer of photoresist.

Dual tone photoresist formulations comprising a photoacid generator are described and employed in fabrication techniques, including methods of making structures on substrates, and more particularly, methods of making electronic devices (e.g. transistors and the like) on flexible substrates wherein two patterns are formed simultaneously in one layer of photoresist.

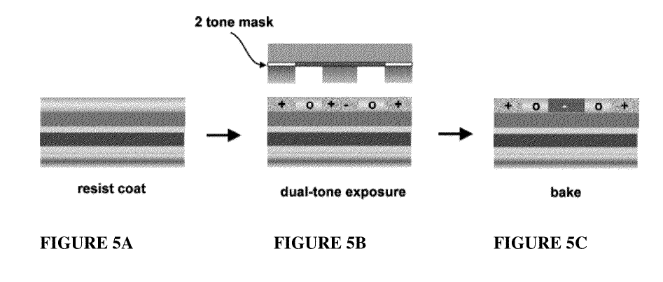

FIG. 5 is a schematic showing one embodiment of a method of printing 2 patterns (isolation and gate) onto 1 layer of resist using a thermally activated dual tone resist (top layer) of the present invention. In one embodiment, the dual-tone thermally activated resist is a) insoluble when not exposed at all to heat or light (“o”), b) soluble in base when exposed to certain wavelengths of light (“+”), and c) insoluble when exposed to both light and heat (“−”). In one embodiment, a two-tone mask is employed (FIG. 5, step B, arrow) and the resist (top layer) is exposed to selected wavelengths of radiation through the mask so as to create a positive response (“+”) for certain exposed regions. For other radiation-exposed regions, a heating step (FIG. 5, step C) is required to get a negative tone (“−”).

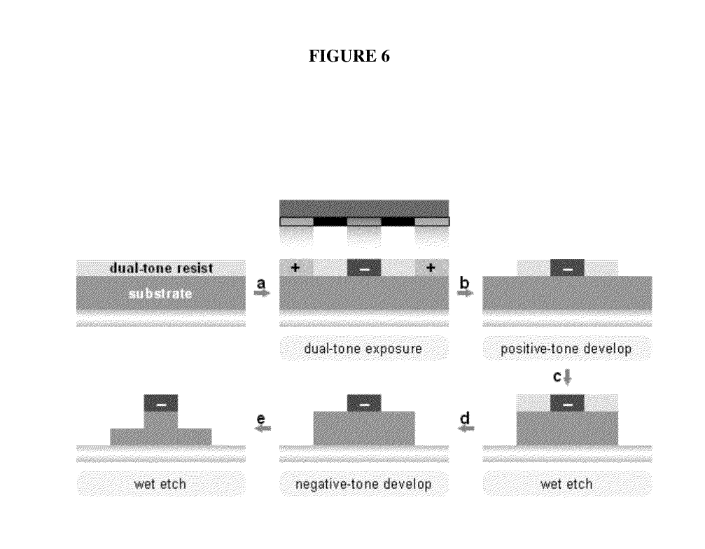

A further embodiment of a self-aligned lithography process with dual-tone photoresist is shown in FIG. 6. During the exposure step (FIG. 6a), a dichromatic photomask containing two sets of device designs simultaneously exposes different photoresist regions to different wavelengths of UV light. One set of the design is transmitted by the filtered sections of the photomask, producing the positive-tone response in the dual-tone photoresist. The second set of the design is transmitted by the transparent of the photomask, producing the negative-tone response in those regions of the photoresist. The photoresist is first developed to realize the positive-tone latent images (FIG. 6b) and then etched (FIG. 6c) to transfer the positive-tone structures into the substrate. The photoresist is then flood exposed and developed again to realize the negative-tone latent images (FIG. 6d) and etched (FIG. 6e) to transfer the negative-tone structures on top of the previous positive-tone structures.

As illustrated in FIG. 6, two device designs are simultaneously imaged into the dual-tone photoresist using a dichromatic photomask. The simultaneous imaging of the two device layers avoids the effects of substrate distortions between conventional photolithography layers and moves the control of the layer-to-layer overlay errors to onmask feature alignments. Since the typical on-mask feature alignment errors are considerably smaller then the layer-to-layer misalignments or substrate distortions, the dual-tone lithography with dichromatic photomask significantly improves the overlay capability of the process.

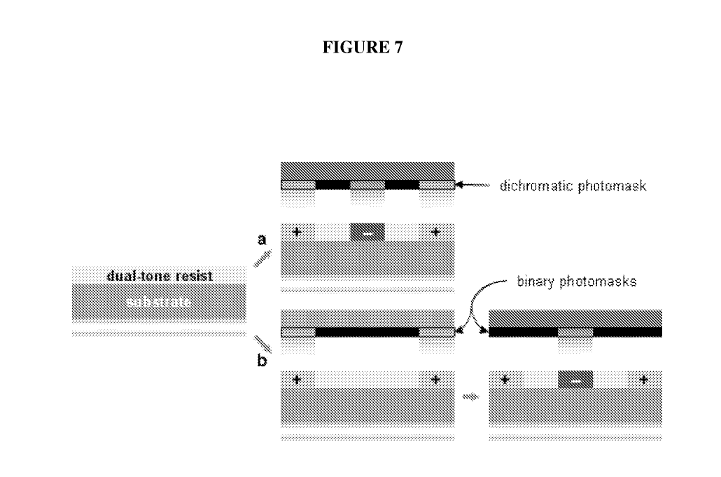

Alternatively, it is possible to carry out dual-tone exposure using binary photomasks instead of dichromatic photomask. Instead of single exposure with one dichromatic photomask to produce both the positive-tone and the negative-tone latent images (FIG. 7a), the dual-tone photoresist is exposed sequentially using two binary photomasks and different wavelengths of UV light to produce the similar positive-tone and negative-tone latent images (FIG. 7b).

The sequential aligned exposures with two binary photomasks are usually done without unloading the substrate between the exposures in a typical manufacturing process. This minimizes the effect of substrate distortion and incurs only mask-to-mask alignment errors between the two patterns. While the typical mask-to-mask misalignment is slightly worse than the on-mask alignment error of a single photomask, it is still significantly better than the layer-to-layer misalignments in a flexible substrate, thereby improving the overlay capability of the process.

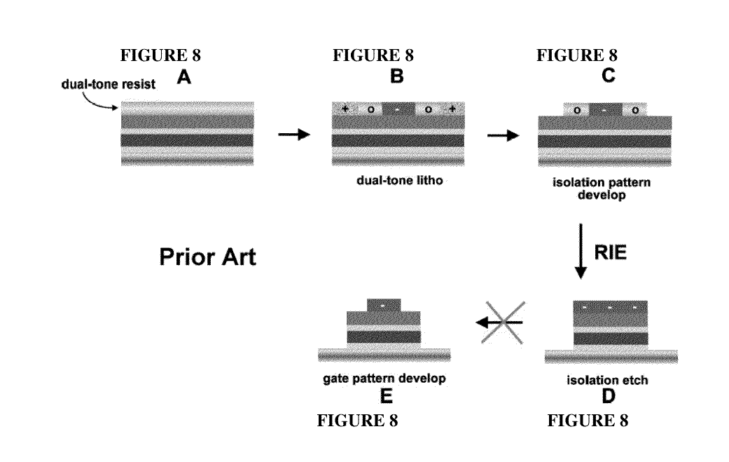

Prior art dual tone resists are not able to maintain the two patterns after further steps. When prior art dual tone resist is used and the resist is flood exposed during plasma or RIE etching, the latent pattern is lost (FIG. 8). The reactive ion etching (RIE) step destroys the latent gate pattern because, with the existing dual tone resist, this exposure activates the crosslinker in the unexposed region (becoming negative tone). In the photoresist system reported by Hinsberg et al., a wet etch process was used to transfer the positive-tone image into the substrate, while maintaining the negative-tone image in the photoresist. This works well, however, when a reactive ion etch (RIE) process is applied for the same etch transfer of positive-tone image, the negative-tone latent image is lost. The loss of the latent image is attributed to the production of UV radiation by the etchant gas plasma during the RIE process, resulting in the unintentional flood exposure of the photoresist as it is being etched. This flood exposure activates the cross-linking reaction between the novolac polymer and the negative-tone sensitizer, producing a negative-tone response in the entire photoresist film and erasing the negative-tone latent image

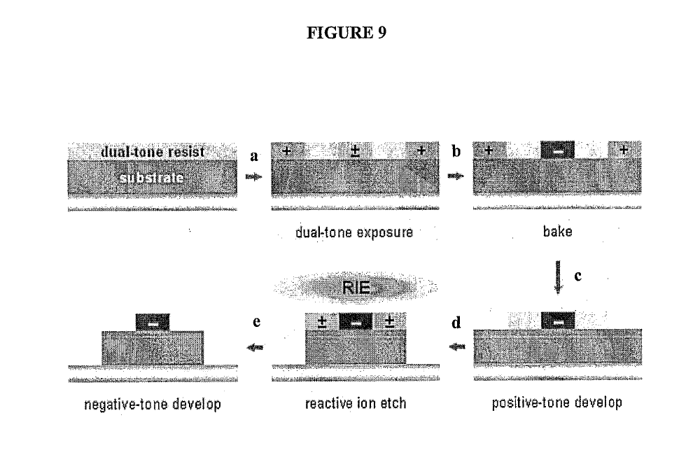

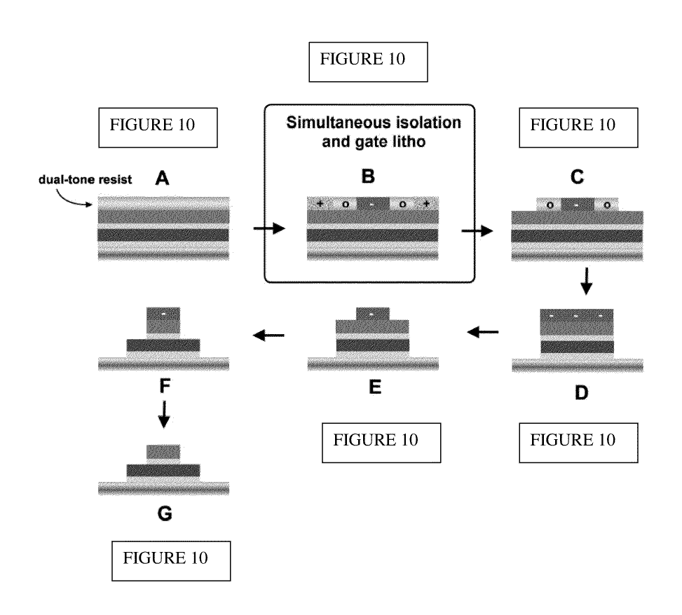

Importantly, the dual-tone resists of the present invention can withstand the flood exposure during RIE (FIG. 9, step d), without turning negative tone. The post-exposure bake step enables the acid-catalyzed cross-linking reaction between the cross-linkers and the novolac polymer, completing the negative-tone response of the photoresist. In contrast, the lack of a bake step after the RIE process prevents the cross-linking reaction from occurring in the flood exposed photoresist, thereby allowing the negative-tone latent image to survive the RIE process. Consequently, the post-exposure bake requirement of the cross-linker provides differentiation between the intentional negative-tone exposure of the dual-tone lithography and the unavoidable flood exposure during the RIE process. FIG. 10 shows one embodiment of an overall process for simultaneous fabrication of the isolation and gate structures using the dual tone resists (step A, top layer indicated by arrow) of the present invention. In this manner, the alignment between isolation and gate becomes mostly a function of mask-to-mask alignment.

The positive-tone photoresist patterns are transfer etched into the silicon oxide substrate using a RIE process with 15 sccm CF₄ and 5 sccm He gas mixture, 150 W etch power, 50 mTorr etch pressure, and a 4 min etch time. The RIE is performed on a Trion RIE etcher. After the CF₄/He etch, a short O₂ plasma ash is applied in the same etcher to remove any of the residual photoresist and etch crust. The O₂ ash process uses 20 sccm O₂ gas flow, 150 W etch power, 50 mTorr etch pressure, and 30 sec etch time. The photoresist is subsequently developed again in the TMAH developer solution to remove the previously unexposed region, leaving behind only the negative-tone patterns. Once developed, a brief O₂ plasma descum is applied to remove any residual photoresist from the aqueous development. The O₂ descum process uses 10 sccm O₂ and 10 sccm He gas mixture, 100 W etch power, 50 mTorr etch pressure, and 20 sec etch time. The negative-tone patterns are transferred into the substrate using the same CF₄/He RIE process as before (15 sccm CF₄ and 5 sccm He gas mixture, 150 W etch power, 50 mTorr etch pressure, and 4 min etch time). Once completed, any remaining photoresist is removed using an acetone and isopropanol solvent rinse.

### EXPERIMENTAL

### Abbreviations:

PGMEA is propylene glycol methyl ether acetate. DNQ is Diazonaphthoquinone sulfonate ester. PAC is photo active compound. TPS is triphenylsulfonium. TMAH is tetramethylammonium hydroxide. AZ®300 MIF Developer is a proprietary aqueous Basic developer of AZ Electronic Materials USA Corp. THPS is tris(4-hydroxyphenyl)sulfonium. DCM is dicholoromethane. TEA is triethylamine. THF is tetrahydrofuran. TMS is tetramethylsilane, (CH₃)₄Si. IR is infrared spectroscopy. FT-IR is Fourier transform infrared spectroscopy. HRMS is high resolution mass spectrometry. HRMS (CI) is high resolution mass spectrometry chemical ionization. KOH is potassium hydroxide. Ppm is parts per million. CDCl₃ is deuterated chloroform. MgSO₄ is magnesium sulfate.

### Material Sources and Synthesis Methods

The i-line positive-tone photoresist (lot 1911-111, Hoechst Celanese Corp, AZ Photoresist Products) comprises novolac polymer and DNQ PAC in PGMEA solvent. A sample of TPS nonaflate was obtained as a generous gift from the AZ Electronic Materials. The 1,4-benzenedimethanol cross-linker was purchased from Sigma-Aldrich and used as received. The AZ 300 MIF base developer, consisting of aqueous tetramethylammonium hydroxide (TMAH) solution, was purchased from the AZ Electronic Materials USA. A sample of tris(4-hydroxyphenyl)sulfonium chloride was obtained as a generous gift from the BASF SE company. Synthesis of the THPS triflate was done by anion metathesis of tris(4-hydroxyphenyl)sulfonium chloride and silver trifluoromethanesulfonate. The 1,4-benzenedimethanol derivative cross-linkers were prepared with the following synthesis methods: All reactions were conducted under a positive nitrogen atmosphere with oven-dried glassware unless otherwise stated. Dry DCM, TEA, and pyridine were obtained by distillation over CaH₂ while dry THF was obtained by distillation over Na/benzophenone. All ¹H and ¹³C NMR spectra were recorded on a Varian Unity Plus 300 MHz instrument. All chemical shifts were reported in ppm downfield from TMS using the residual protonated solvent as an internal standard (CDCl₃, ¹H 7.26 ppm and ¹³C 77.0 ppm). HRMS (CI) was obtained on a VG analytical ZAB2-E instrument. IR data were recorded on a Nicolet Avatar 360 FT-IR and all peaks are reported in cm⁻¹. All chemicals were purchased from Sigma-Aldrich and used as received unless otherwise stated.

### 1,4-bis-acetoxymethyl benzene

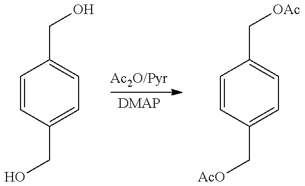 [SMILES: OCc1ccc(CO)cc1 ; CC(=O)OCc1ccc(COC(C)=O)cc1]

A 50 mL RBF was charged with dimethylaminopyridine (88 mg, 0.7 mmol), acetic anhydride (13.7 mL, 145.0 mmol), pyridine (11.7 mL, 145.0 mmol), 1,4-benzenedimethanol (2.0 g, 14.5 mmol), and a stir bar. This solution was stirred at rt for 24 h then diluted with ether (200 mL). The organic layer was thoroughly rinsed with 1 M KOH (4×100 mL), followed by rinsing with 1 M CuSO₄ (2×50 mL). The organic layers were combined, dried over MgSO₄, and concentrated in vacuo to yield 1,4-bis-acetoxymethyl-benzene as a white crystalline solid (mp=54-56° C.) (20.7 g, 89%); ¹H NMR (CDCl₃) δ ppm: 7.351 (s, 4H), 5.094 (s, 4H), 2.090 (s, 6H); ¹³C NMR (CDCl₃) δ ppm: 170.736, 135.932, 128.386, 65.811, 20.909; IR (NaCl) cm-1; 2960, 2897, 1722, 1227, 1018; HRMS (CI): 245.0787 calc, 245.0784 found.

### 1,4-bis-methoxymethyl benzene

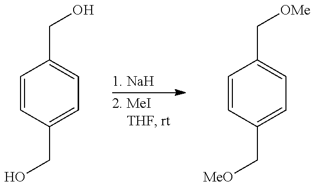 [SMILES: OCc1ccc(CO)cc1 ; COCc1ccc(COC)cc1]

A 50 mL RBF was charged with NaH (2.3 g, 57.9 mmol, 60% dispersion in mineral oil), THF (10 mL), and a stir bar. The suspension was vigorously stirred as 1,4-benzenedimethanol (2.0 g, 14.5 mmol) was added slowly at rt. Upon complete evolution of gas, iodomethane (9.0 mL, 145 mmol) was slowly added. The solution was stirred for 24 h, and then the excess iodomethane was removed in vacuo. The remaining suspension was dissolved in ether, and the salts were removed by filtration. 1,4-bis-methoxymethylbenzene was isolated by distillation (75-77° C., 0.83 torr) in good yield (2.0 g, 81%) as a clear liquid; ¹H NMR (CDCl₃) δ ppm: 7.301 (s, 4H), 4.425 (s, 4H), 3.351 (s, 6H); ¹³C NMR (CDCl₃) δ ppm: 137.406, 127.546, 74.189, 57.784; IR (NaCl) cm-1:2982, 2925, 2852, 1380, 1123, 1099, 809; HRMS (CI): 165.0916 calc, 165.0922 found.

### 1,4-bis-tertbutoxycarbonyloxymethyl benzene

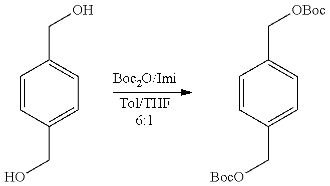

A 100 mL RBF was charged with imidazole (40 mg, 0.6 mmol), di-tert-butyl dicarbonate (758 mg, 3.5 mmol), toluene (30 mL), THF (5 mL), and a stir bar. After stirring for 10 min, 1,4-benzenedimethanol (200 mg, 1.5 mmol) was added, and the reaction was stirred at rt for 48 h. DCM was added to the reaction which was then rinsed with brine, dried over MgSO₄, and concentrated in vacuo. This crude mixture was subjected to flash column chromatography (9:1 Hex:EtOAc) to yield 1,4-bistertbutoxycarbonyloxymethyl-benzene as a white crystalline solid in moderate yield (234 mg, 49.6%); mp=71-74° C.; ¹H NMR (CDCl₃) δ ppm: 7.364 (s, 4H), 5.079 (s, 4H), 1.482 (s, 18H); ¹³C NMR (CDCl₃) δ ppm: 153.368, 135.772, 128.373, 82.331, 68.246, 27.739; IR (KBr) cm-1:2984, 1738, 1396, 180, 1157, 1087; HRMS (CI): 339.1808 calc, 339.1810 found.

Procedure adapted from Basel, Y.; Hassner, A. J. Org. Chem. 2000, 65, 6368-6380.

### Lithography Development

Silicon wafers were used for the initial photoresist print tests, and stainless steel foils were used for the final testing of the photoresist on a flexible substrate. The substrates were treated with a commercial adhesion promoter (AP310, Silicon Resources Inc.) to ensure good adhesion between the photoresist and the substrate surface. The photoresists were spin-coated and baked to produce 1 um films, then measured using a stylus profilometer (Dektak 6M, Veeco).

The exposures were done with a broadband UV curing system (Novacure, EXFO) operating at 8 mW/cm² at the substrate plane. A 345 nm long pass filter was applied above the photomask for the positive-tone exposure, limiting the exposure UV light to those greater than 345 nm wavelengths in the positive-tone regions. Broadband exposure was used for the negative-tone exposure without any filter.

The dual-tone exposure and bake conditions were optimized to allow the positive tone latent image to develop in less than 60 seconds in the aqueous TMAH developer, while maintaining the negative-tone film loss at less than 5%. The positive-tone image development was marked by the complete dissolution of the photoresist film in the positive-tone exposed region. The negative-tone film loss was measured as the ratio of the negative-tone exposed photoresist film thickness before and after the positive-tone development. Increasing the exposure time and/or dose favorably reduced both the positive-tone develop time and the negative-tone film loss, but adversely lowered the throughput of the dual-tone lithography process. Increasing the post-exposure bake temperature and/or time favorably reduced the negative-tone film loss, but had minimal impact on the positive-tone develop time.

Subsequent to development of the positive-tone image, a broadband flood exposure was applied to the entire sample without additional bake to activate the unexposed portion of the photoresist. This flood exposure rendered the unexposed region of the photoresist soluble to aqueous base developer, which was later removed to realize the negative-tone image from the dual-tone exposure step.

### Etch Development

The positive-tone and the negative-tone patterns in the photoresist were each transferred into the silicon oxide substrate using the RIE process. A reactive ion etcher (Oracle III, Trion Technology) located in the Microelectronics Research Center (MRC) cleanroom of the J. J. Pickle Research Campus was used for the transfer etch portion of the dual-tone photoresist print tests.

The etch data shown in FIG. 16 suggests that the CF₄/He gas mixture had the highest selective between silicon oxide etch and photoresist film loss at a given etch power and pressure, compared to that of the CF₄/O₂ mixture and the pure CF₄ etch gas. Based on these etch data, the etch recipe of 15 sccm CF₄, 5 sccm O₂, 50 mTorr, and 150 W was used for all subsequent dual-tone photoresist print tests.

Etch tests with the patterned photoresist samples revealed the formation of an insoluble crust on top of the previously unexposed regions of the photoresist film, as shown in FIG. 18. The aqueous base developer visibly undercuts the photoresist (FIG. 18B), leaving behind an insoluble crust (FIG. 18C). This insoluble crust impeded the subsequent negative-tone etch process, introducing irregular etch defects in the etched negative-tone pattern.

Two process changes were made to mitigate the etch crust and its effect on the negative-tone image development. The flood exposure of the previously unexposed dualtone photoresist was moved to precede the positive-tone etch step instead of following the said etch step, ensuring that the crust formed during etch did not interfere with the flood exposure of the photoresist. A short O₂ plasma ash was also added right after the positive-tone etch step to remove the crust prior to the negative-tone image development. The combination of the two changes was able to overcome the insoluble photoresist crust and enabled etching of the negative-tone images into the substrate.

In summary, the positive-tone photoresist patterns were transfer etched into the silicon oxide substrate using a RIE process with 15 sccm CF₄ and 5 sccm He gas mixture, 150 W etch power, 50 mTorr etch pressure, and a 4 min etch time. The RIE was done on a Trion RIE etcher. After the CF₄/He etch, a short O₂ plasma ash was applied in the same etcher to remove any of the residual photoresist and etch crust. The O₂ash process used 20 sccm O₂ gas flow, 150 W etch power, 50 mTorr etch pressure, and 30 sec etch time. The photoresist was then developed again in the TMAH developer solution to remove the previously unexposed region, leaving behind only the negative-tone patterns. Once developed, a brief O₂ plasma descum is applied to remove any residual photoresist from the aqueous development. The O₂ descum process used 10 sccm O₂ and 10 sccm He gas mixture, 100 W etch power, 50 mTorr etch pressure, and 20 sec etch time. The negative-tone patterns were transferred into the substrate using the same CF₄/He RIE process as before (15 sccm CF₄ and 5 sccm He gas mixture, 150 W etch power, 50 mTorr etch pressure, and 4 min etch time). Once completed, any remaining photoresist was removed using an acetone and isopropanol solvent rinse.

### Print Tests

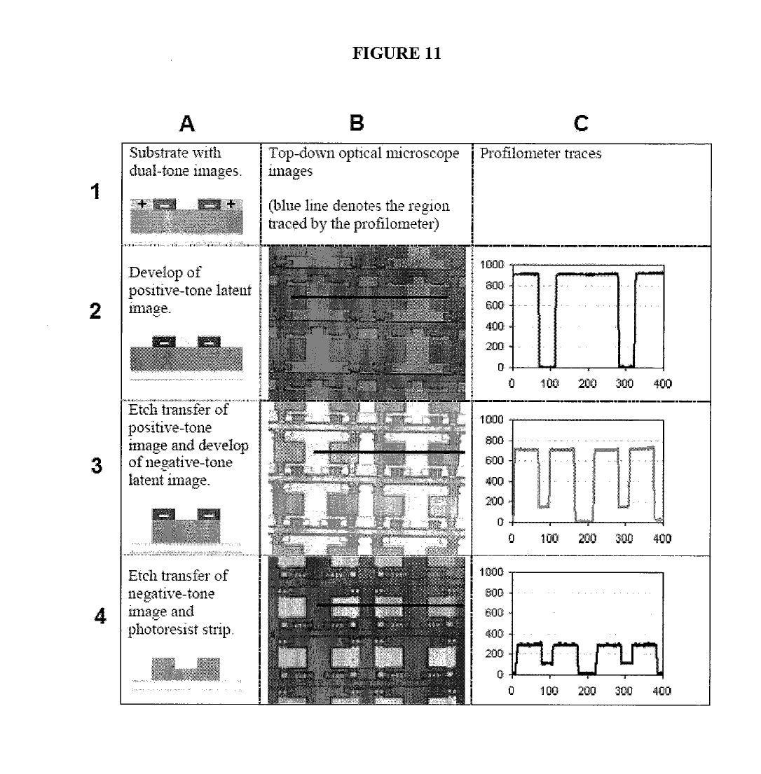

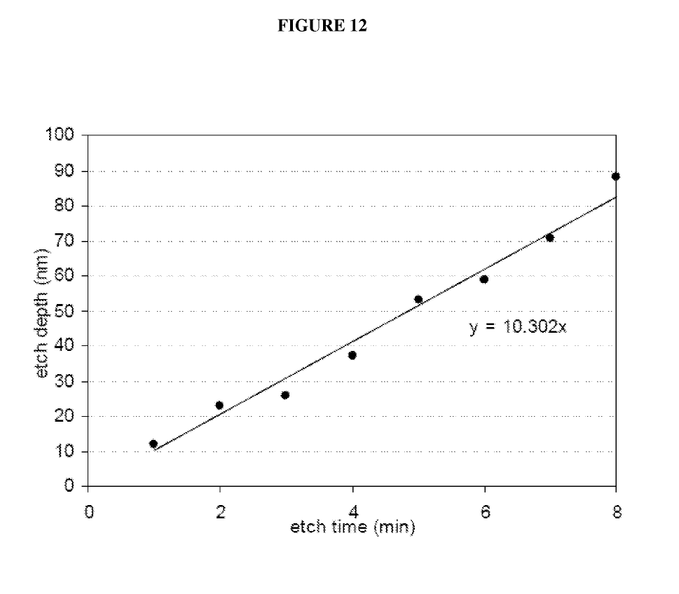

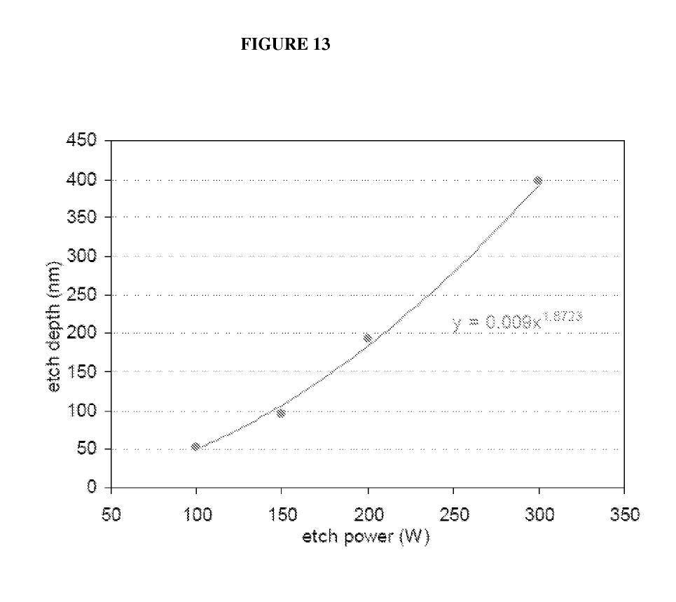

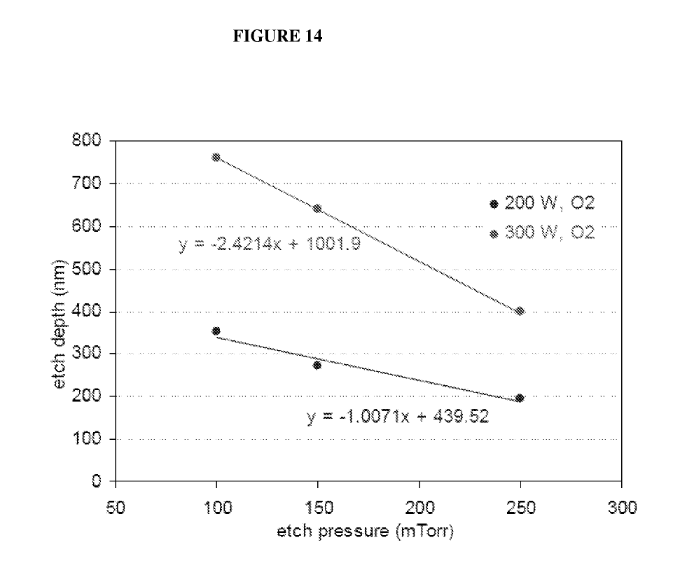

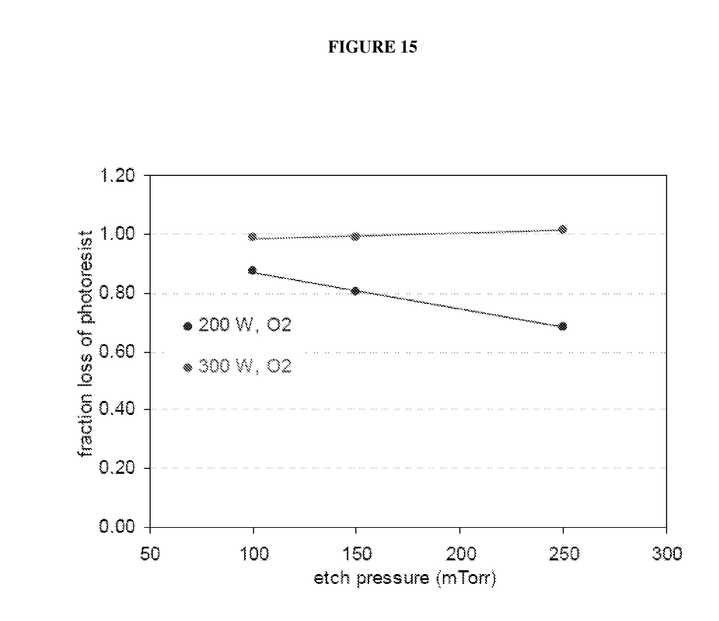

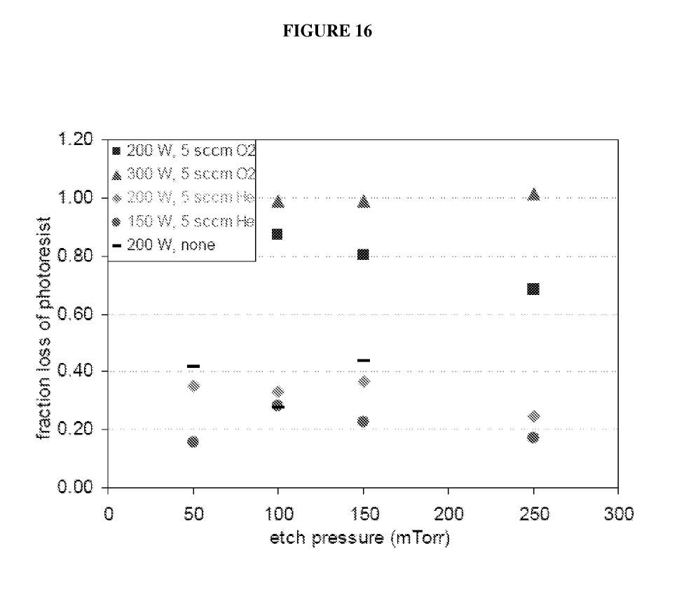

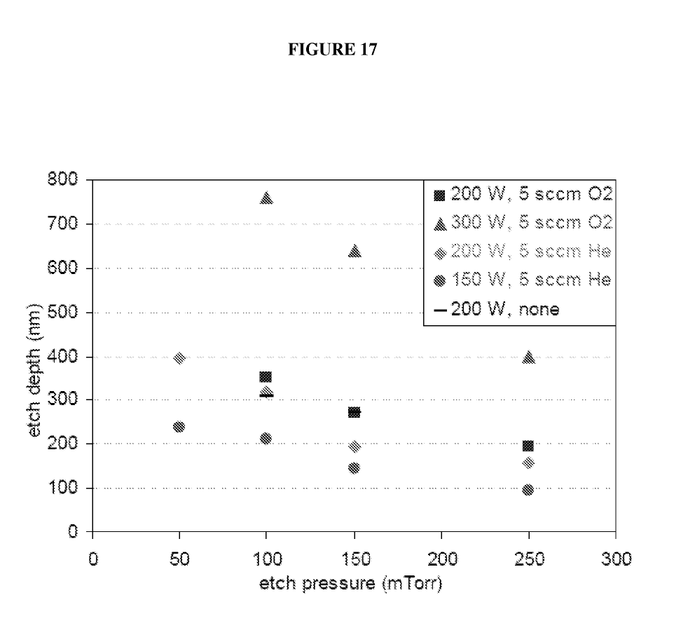

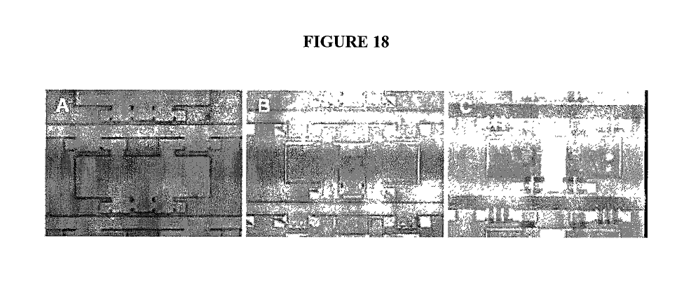

FIG. 11 shows optical microscope images and the corresponding profilometer traces of a patterned photoresist sample on a silicon wafer at several process stages. A top-down optical microscope image in row 2 shows a sample device area, with the dark blue line denoting the profilometer scan area across the positive-tone photoresist. The profilometer trace shows a 900 nm tall photoresist structure after the positive-tone development.

The sample was then etched by RIE to transfer the positive-tone image into the substrate, and developed again to remove previously unexposed photoresist, leaving behind the negative-tone device image. Row 3 shows a top-down image of the dual-tone photoresist sample with the positive-tone image etched into the substrate and negative-tone photoresist image left. The profilometer trace shows approximately 550 nm of photoresist remaining after the positive-tone structures are etched into the silicon substrate.

Finally, the sample was etched again by RIE to transfer the negative-tone image into the substrate, then stripped of the photoresist, leaving behind the two aligned layers of device structures in the substrate. Row 4 shows a top-down image of the dual-tone photoresist sample with both positive-tone and negative-tone images etched into the substrate. The profilometer trace shows ˜100 nm tall positive-tone structures and ˜200 nm tall negative-tone structures.

### Alternative Crosslinkers

The 1,4-benzenedimethanol and its derivatives (1,4-bis-methoxymethyl-benzene, 1,4-bis-acetoxymethyl-benzene, and 1,4-bis-tertbutoxycarbonyloxymethyl-benzene) all have moderate solubility in PGMEA, and successfully produced a negative-tone response with the application of acid and heat. The derivatives differ in the acid labile protecting group used to cap the methanol cross-link functionality: methoxy, acetoxy, and tertbutoxycarbonyloxy (t-boc). The influence of the protecting groups on the negative tone response of the dual-tone photoresist was measured by the change in the threshold post exposure bake (PEB) temperature required for the negative-tone cross-link reaction. The effects of the different protecting groups were found to be less than expected. The change in threshold PEB temperature across the four different cross-linkers was less than 20° C., and all of the structures were able to produce sufficient cross-linking reactions at 110° C. PEB temperature to realize the negative-tone image. As a result, the commercially available 1,4-benzenedimethanol (Sigma-Aldrich Co), was chosen for all subsequent dual-tone photoresist formulations.

1. A method of making two patterns in one layer of photoresist, comprising the steps of:
(a) providing a substrate, a dual-tone photoresist, a source of radiation, and a two-tone mask, said mask having transparent areas, opaque areas and areas transparent to selective wavelengths of radiation, wherein said photoresist comprises a thermally activated, chemically amplified crosslinker and a photoacid generator;
(b) forming one or more thin layers over said substrate;
(c) coating the top layer with said dual-tone photoresist;
(d) exposing said photoresist to radiation, said radiation coming from said source of radiation and passing through said mask, said mask positioned on top of said photoresist under conditions such that two patterns are generated in said layer of photoresist, said patterns defined by i) radiation-exposed regions of the photoresist having a positive tone response, ii) unexposed regions of the photoresist, and iii) at least one radiation-exposed region of the photoresist capable of a negative tone response; and
e) exposing said at least one radiation-exposed region of the photoresist capable of a negative tone response to heat wherein a negative tone response is achieved.

2. The method of claim 1, wherein said crosslinker comprises 1,4-benzenedimethanol.

3. A method of making two patterns in one layer of photoresist, comprising the steps of:
(a) providing a substrate, a dual-tone photoresist, a source of radiation, and a two-tone mask, said mask having transparent areas, opaque areas and areas transparent to selective wavelengths of radiation, wherein said photoresist comprises a thermally activated, chemically amplified crosslinker and a photoacid generator;
(b) forming one or more thin layers over said substrate;
(c) coating the top layer with said dual-tone photoresist;
(d) exposing said photoresist to radiation, said radiation coming from said source of radiation and passing through said mask, said mask positioned on top of said photoresist under conditions such that two patterns are generated in said layer of photoresist, said patterns defined by i) radiation-exposed regions of the photoresist having a positive tone response, ii) unexposed regions of the photoresist, and iii) at least one radiation-exposed region of the photoresist capable of a negative tone response;
e) exposing said at least one radiation-exposed region of the photoresist capable of a negative tone response to heat wherein a negative tone response is achieved;
f) developing the photoresist by treatment with a solvent, under conditions whereby the radiation-exposed regions of the photoresist having a positive tone response are removed; and
g) subjecting said one or more layers to reactive ion etching, wherein the unexposed regions of the photoresist do not become negative tone.

4. The method of claim 3, wherein said substrate is a flexible substrate.
